(19) United States
(12) Patent Application Publication
(10) Pub. No.: US 2026/0314335 A1
(43) Pub. Date: Oct. 8, 2026

(54) MACHINE LEARNING-BASED PRODUCT TEST-TIME REDUCTION FOR TEST FLOW, MANUFACTURE, DESIGN, AND OPERATION OF INTEGRATED-CIRCUIT DEVICES

(71) Applicant: NXP B.V., Eindhoven (NL)

(72) Inventors: Mehul D. Shroff, Austin, TX (US); Nguyen Nguyen, Round Rock, TX (US)

(21) Appl. No.: 19/097,901

(22) Filed: Apr. 2, 2025

(51) Int. Cl. H01L 21/66; G01R 31/28

(52) U.S. Cl. CPC H10P 74/207; G01R 31/2851

(57) ABSTRACT

A method, apparatus, and system for fabricating and testing integrated-circuit (IC) devices include providing an IC device containing circuitry for performing electrical functions of the IC device, and then applying a plurality of tests to the circuitry to test the electrical functions of the IC device, where the plurality of tests is generated with a test-time reduction methodology, which uses a combination of association-analysis processing and greedy-algorithm processing to evaluate fail-test data from an input test dataset to identify and eliminate redundant or unnecessary tests from the input test dataset to generate the plurality of tests.

### BACKGROUND OF THE INVENTION

### Field of the Invention

The present disclosure is directed in general to the field of semiconductor device technologies. In one aspect, the present disclosure relates to the design, testing, and manufacture of integrated circuits.

### Description of the Related Art

Modern semiconductor products can include diverse circuits performing various complex functions, large arrays of embedded memories, dense logic, and multiple supply and input/output pads for different voltage domains. With aggressive feature sizes, new materials, and novel device architectures used to make the chips on advanced technology nodes, new defects and failure modes have emerged. As a result, new fault models, tests, and increased test coverage are needed to obtain the required quality levels in the field.

Manufacturers of automotive systems and vehicles are demanding increasingly stringent quality standards from semiconductor manufacturers, with failure thresholds measured in defective parts per billion. This requires higher levels of circuit coverage in testing and further increases test time. Automotive products can require thousands of tests, both functional and parametric, to assess the health and robustness of the parts and screen out defective parts before being shipped to customers. Tests may be done at the wafer level following completion of wafer processing (unit probe) and on packaged dice after the assembly and packaging process (final test). These tests may be done across multiple voltages (including guard-banded voltages) and temperatures (e.g., cold, room, hot) and may include controlled stressing at highly elevated voltages and/or temperatures (e.g., burn-in, high-voltage stress test).

Testing imposes significant costs, typically in the range of 5-10% of the total manufacturing cost. Tester capacity and throughput are also being challenged by increasing volumes of semiconductor products as their use in established and novel applications proliferates. As technologies and products mature and yield improves, there is motivation to reduce test costs and time to meet profitability and throughput goals, respectively. However, it is imperative to do this without causing test escapes into the field.

As known to those skilled in the art, various strategies for test-time reduction (TTR) have been proposed, such as removing tests that do not fail in sample datasets of interest, which may be of varying sizes. Alternatively, such tests can be moved to a separate test program that is used in sampling during volume production. Another TTR strategy is to remove tests in one insert that are covered at other inserts (e.g., unit probe vs. final test) or temperatures and may therefore be redundant. Another TTR strategy is to re-order the test sequence to have tests with higher failure rates run earlier in the flow. This approach primarily works with stop-on-fail testing, where testing on a part is stopped once it fails a test. Another TTR strategy employs adaptive testing which optimizes the tests and limits based on feed-forward data from the manufacturing flow and/or feedback data from prior testing. This may include testing the majority of parts with a subset of tests and the remaining parts with all tests, based on various criteria used to assess risk.

The availability of powerful servers, cloud computing, and machine learning (ML) techniques provide semiconductor product and test engineers with new tools to develop more sophisticated approaches for TTR. Database and analysis tools may also have embedded solutions to implement TTR. Product engineers can identify candidate tests for removal and assess them on validation units and historical data to assess the TTR vs. quality trade-off. Other techniques are based on using greedy algorithms, where the minimum set of tests that cover all failures (faults) is retained in the test program. An optional weighting factor, based on test time and number of prior failures, may be applied to each test based on its criticality.

In addition, canonical correlations (multi-variate analysis of variance) may be used to reduce parametric radio-frequency and analog tests by initially partitioning tests into remove and keep categories and then moving tests from one category to another based on results from evaluations done on appropriate sample sets. Another approach is to use a fine-grained adaptive final-test strategy. Parametric test results are used to train ML models. Parts are classified into quality levels, which are used to build a probabilistic model for die-level adaptive testing. In another approach, a decision is made to test a wafer with a full or reduced test set based on process-parametric results to assess the impact of process variations on the wafer. Principal Components Analysis is used to classify wafer signatures into k-mean clusters to determine the appropriate test suite. In another approach, a fast correlation-based filter and weighted naïve Bayesian model are used to identify an optimal test subset.

In another approach, high-quality test patterns (which can detect multiple fault modes) are identified and placed at the beginning of the test program. The sequence of test vectors is continuously updated based on real-time data and may be used to optimize test time. In another approach, a “virtual probe” is used with wafer-level spatial correlations to predict performance parameters of all dice based on testing subsets of dice at selected locations. This approach does not work for failures due to random defects that do not exhibit spatial signatures. A one-pass test-selection method that selects tests based on their effectiveness at detecting faults compared to previous tests and optimizing the insertion order based on a greedy algorithm has also been demonstrated. Tests that uniquely fail are prioritized over multiple tests that fail together on bad dice. A Boolean minimization technique has also been proposed for use for test reduction.

In another approach, a weighted-ranking algorithm using support vector machines is used to classify and reorder the test-pattern sequence. A Bayesian network-based approach may also be used to select the set of parametric tests that can most efficiently detect faults. In another approach, Bayesian statistics are used to create a fail rate for each test and dynamically reorder tests adaptively. The learned test order is determined from a sample of the wafers and continue-on-fail (CoF) testing. The learned test order is the stop-on-fail (SoF) test flow, which minimizes the wafer total test time for the selected wafers.

As seen from the foregoing, existing test solutions suffer from high costs, significant complexity, slow computation times, limited statistical rigor, and unacceptable escape risk. Such conventional test reduction solutions rely heavily on test-engineering experts making decisions using design timing, data, and an understanding of the ranges of test voltages and test temperatures to find test corners, but such solutions do not provide engineering rigor or statistical rigor required by high reliability applications. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description of a preferred embodiment is considered in conjunction with the following drawings.

FIG. 1 illustrates the relation between the antecedent (A) and the consequent (C) in an association analysis rule.

FIG. 2 is a table comparison of association rules being used in a retail application and in a semiconductor testing application in accordance with selected embodiments of the present disclosure.

FIG. 3 illustrates a simplified flow chart for a fast, statistical, machine-learning approach for product test reduction in accordance with first selected embodiments of the present disclosure.

FIG. 4 illustrates the results of an associations analysis of an antecedent test and consequent test identify an antecedent test that is a candidate for removal because the antecedent test results are covered by a consequent test in accordance with selected embodiments of the present disclosure.

FIG. 5 illustrates the results of an association analysis of an antecedent test and consequent test which identifies an antecedent test and a consequent test which fail in tandem in accordance with selected embodiments of the present disclosure.

FIG. 6 illustrates the results of a 1:M association analysis of an antecedent test with two consequent tests in accordance with selected embodiments of the present disclosure.

FIG. 7 illustrates a simplified process flow chart for a greedy algorithm to identify tests for removal in accordance with selected embodiments of the present disclosure.

FIG. 8 illustrates a simplified flow chart for a fast, statistical, machine-learning approach for product test reduction in accordance with second selected embodiments of the present disclosure.

FIG. 9 illustrates a chart comparison of lift and z-score for a dataset in accordance with second selected embodiments of the present disclosure.

FIG. 10 depicts a simplified block diagram of a computer data processing system which uses a fast association analysis for statistical test-time reduction methodology to identify and eliminate redundant or unnecessary tests from an input test dataset in accordance with selected embodiments of the present disclosure.

FIG. 11 depicts a simplified flow diagram of a method for fabricating an integrated circuit device in accordance with selected embodiments of the present disclosure.

### DETAILED DESCRIPTION

A methodology for designing, fabricating, and testing integrated circuit (IC) devices is described for using machine-learning techniques and association-rule analysis to identify and eliminate redundant or unnecessary IC device tests while ensuring that the test-cost savings do not compromise test quality. In selected embodiments, a Fast Association Analysis for Statistical Test-Time Reduction (FAASTTR) methodology for functional tests uses a combination of association analysis (AA), OR-based indirect associations, and a greedy algorithm to evaluate failing-test data to identify and eliminate redundant or unnecessary tests without compromising the quality of shipped parts. The disclosed FAASTTR methodology is fast, highly scalable, and statistically rigorous. Using a continue-on-fail (CoF) (also known as pass-through or deferred-binning) testing, where a product is tested through all tests in the program to log all failing tests, the FAASTTR methodology uses parts failing one or more tests in a test program to identify redundant tests for potential removal. With the availability of ganged (parallel) testing in state-of-the-art test systems to simultaneously test multiple dice, CoF testing is highly feasible. In selected embodiments, the FAASTTR methodology can also be adapted for parametric tests by first converting results to pass/fail based on the test limits.

In selected embodiments of the disclosed FAASTTR methodology, a machine-learning based combination of association-analysis processing and greedy-algorithm processing to produce OR-based indirect associations is utilized to identify highly correlated tests for removal to reduce test time without increasing (or with low and quantified) escape risk. As a preliminary step in the FAASTTR methodology, sample-size and analysis criteria parameters are established in an initialization step to (further) optimize the test-reduction process by optimizing the tests based on minimum levels of occurrence in the dataset. When additional test-time reduction is needed, the initialization step may optionally identify additional tests for removal based on low/known failure rates. Prior to performing the association-analysis processing and greedy-algorithm processing, the input dataset is evaluated to initially identify “non-failing” tests for removal that have not failed in the dataset. As part of the association-analysis processing, the FAASTTR methodology identifies directions of associations (necessary vs. sufficient) among tests that are highly positively correlated, selects the “necessary” test(s) [consequent] to keep, and removes the “sufficient” test(s) [condition/antecedent] based on 100% confidence. For tests with high levels of occurrences, the FAASTTR methodology may implement checks to detect whether they are uniformly distributed across the dataset or correlated with specific lots, wafers, hardware, or timeframe (to avoid generalizing special/unique causes). For tests with high levels of occurrences, the FAASTTR methodology may optionally allow such tests to be retained in the test program, such as by pre-removing them from the test-reduction process. In addition, unique handling is applied as an association-analysis post-processing step to two or more fully correlated (necessary and sufficient) tests to identify at most one test to retain. To enhance the statistical rigor of the FAASTTR methodology, the association-analysis post-processing step may also evaluate the statistical significance of identified test associations using a z-score and p-value instead of the conventional lift metric. As part of the greedy-algorithm processing, the FAASTTR methodology identifies a plurality of logically combined tests (using OR logic) that together are determined as necessary for one (or more) tests that can then be identified for removal. To enhance the statistical rigor of the FAASTTR methodology, the greedy-algorithm processing step may also evaluate the statistical significance of identified test associations using a z-score and p-value instead of the conventional lift metric. In selected embodiments, the disclosed FAASTTR methodology may include post-processing steps that are applied to the results of the association-analysis processing and greedy-algorithm processing to allow tests that are identified but cannot be removed in the association-analysis processing step (direct associations) to be checked again in the processing step (indirect associations). In addition, selected embodiments of the FAASTTR methodology may include post-processing steps that are applied to the results of the association-analysis processing and greedy-algorithm processing to resolve conflicts, such as by removing an entire cluster of fully correlated tests if the cluster is covered by at least one other test that is necessary for the cluster but not sufficient. The disclosed FAASTTR methodology also compares the results of the association-analysis processing and greedy-algorithm processing to resolve conflicts, such as by performing conflict-resolution processing between tests identified for removal in certain rules and tests identified for keeping in other rules. The disclosed FAASTTR methodology may also estimate escape risk based on established quality statistics and metrics, which may also include determining whether tests identified for removal are covered by other tests in subsequent test inserts.

In this disclosure, an improved integrated circuit (IC) design, structure, testing methodology, and manufacturing process are described for designing, fabricating, testing, and operating IC devices to address various problems in the art where various limitations and disadvantages of conventional solutions and technologies will become apparent to one of skill in the art after reviewing the remainder of the present application with reference to the drawings and detailed description provided herein. Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the product or test engineer's specific goals, which will vary from one implementation to another. While such a development effort might be complex and time-consuming, it would nevertheless be a routine undertaking for those of ordinary skill in the art having the benefit of this disclosure. Such descriptions and representations are used by those skilled in the art to describe and convey the substance of their work to others skilled in the art. It is also noted that, throughout this detailed description, certain elements in the figures are illustrated for simplicity and clarity and have not necessarily been drawn to scale. In addition, the dimensions of some of the elements in the figures may be exaggerated relative to other elements to help improve the understanding of the embodiments of the present disclosure. Further, reference numerals have been repeated among the drawings to represent corresponding or analogous elements.

As a preliminary matter, it will be appreciated by those skilled in the art that IC device testing may be applied to IC circuitry to verify functionality and identify defects at wafer (die sort or unit probe) and package (final test) levels using various techniques, like logic function, electrical characteristic, and reliability tests. Such IC device tests may be applied by providing signal and/or voltage inputs to the IC input/output or reference voltage pads and measuring/detecting selected IC device outputs. In addition or in the alternative, IC device tests may be applied to special-purpose test circuitry in the IC device (e.g., boundary scan-chain JTAG circuits) for testing electrical functions of the IC device. For example, wafer-level tests (also known as die sort or unit probe) can be applied to integrated circuits on the wafer before they are cut into individual chips by using a probe to contact the individual chips on the wafer for identifying and marking any defective dice. In addition, package-level tests (also known as final test) can be applied after the wafers are cut and the individual chips are packaged by using a handler, test socket, and tester to conduct comprehensive electrical and functional testing of the packaged ICs. Such package-level tests include, but are not limited to logic function testing (which verifies that the IC performs its intended logic function by testing its inputs and outputs under various conditions), electrical characteristic testing (which tests the electrical characteristics of the IC, such as voltage, current, and power consumption, to ensure it operates within specified parameters), time characteristic testing (which evaluates the IC's performance at different clock frequencies, crucial for high-speed applications), temperature-characteristic tests (which assess the IC's performance under various temperature conditions, ensuring reliable operation in different environments), reliability testing (which tests the IC's ability to operate reliably over long periods, under different operating conditions, to ensure long term durability and functionality), and in-circuit testing (which verifies component functionality, such as shorts, opens, resistance, and capacitance, on a printed circuit board assembly).

As understood by persons skilled in the art, an association analysis rule defines a mathematical function is represented as an implication of the form “A→C”, where A and C are itemsets (sets of items) and “→” signifies “implies” to essentially state that if A occurs, then C is likely to occur as well. In this example rule, A is called the “antecedent” (the “if” part) and C is the “consequent” (the “then” part) of the rule. A may also be referred to as the “Condition.” Association analysis (also known as market-basket analysis) is a widely used unsupervised machine-learning approach in the retail industry where association analysis is used to analyze purchase receipts and identify which items are being purchased together (e.g., bread and butter, peanut butter and jelly) or to identify which projects are not being purchased together (e.g., tea and coffee, sugar and artificial sweeteners). The results are patterns linking different products, which can be used to help make marketing and business decisions.

Association analysis results in the generation of association rules measuring the probability of the joint occurrence of antecedent (also known as condition) and consequent items in the dataset. For example, people who buy butter (antecedent) may also buy bread (consequent). In accordance with the present disclosure and as explained more fully hereinbelow, a market-basket association analysis can be adapted for testing of semiconductor devices by replacing transaction receipts with semiconductor-device part identifiers (ID) (e.g., an Electronic Chip Identification (ECID)) and by replacing the purchased items with failing tests. For semiconductor-device testing, the antecedent represents the candidate test (only one per rule) to be removed, and the consequent represents the test(s) to be retained. Anti-correlation is not relevant for semiconductor testing.

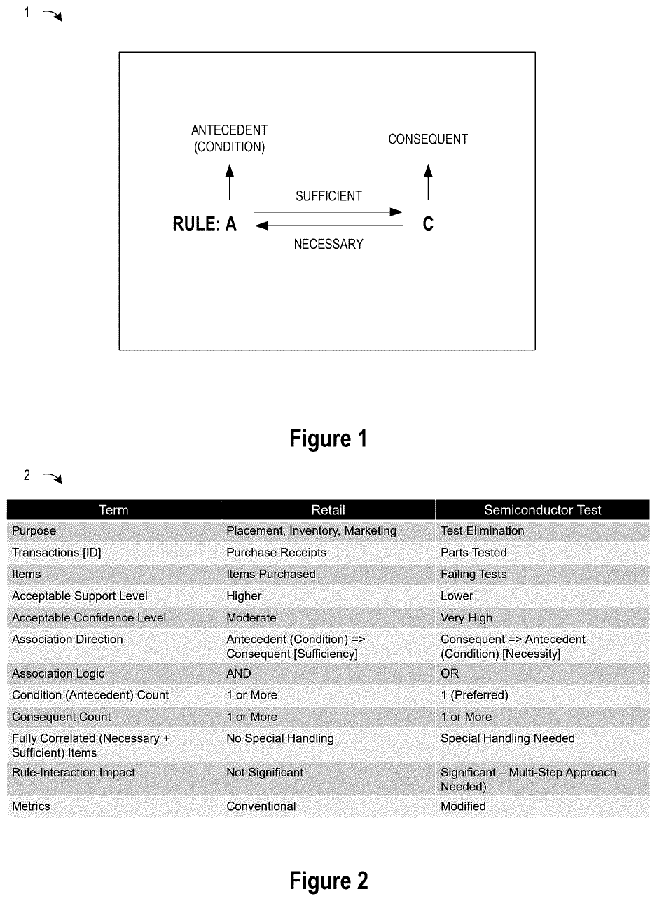

For an improved understanding of selected embodiments of the present disclosure, reference is now made to FIG. 1 which illustrates an association-analysis rule 1 having the following relation between the antecedent (A), also known as the condition, and the consequent (C): A⊆C.

In the depicted association-analysis rule 1, the mathematical relationship “A→C” indicates that if A occurs, then C may occur (mathematical sufficiency). In addition, the mathematical relationship “A→C” indicates A may not occur without C also occurring.

In addition, the depicted mathematical relationship “A←C” indicates that if C does not occur, then A may not occur (mathematical necessity). In addition, the mathematical relationship “A←C” indicates that C may occur without A also occurring.

There are several key metrics for association-analysis rules, which are based on computing the occurrence levels (also known as support) of the antecedent, consequent, and rule. A first metric value “N” specifies the dataset size (failing units only). In addition, the metric value “n[A]” (count [Antecedent]) specifies the count of occurrence of antecedent in the dataset. In addition, the metric value “s[A]” (support [Antecedent]) specifies the probability of occurrence of an antecedent in the dataset. In addition, the metric value “n[C]” (count [Consequent]) specifies the count of occurrence of a consequent in the dataset. In addition, the metric value “s[C]” (support [Consequent]) specifies the probability of occurrence of a consequent in the dataset. In addition, the metric value “n[R]” (count [Rule]) specifies the count of occurrence of the association analysis rule in the dataset.

Based on these metric values, the “support” or probability of occurrence of the antecedent in the dataset may be computed as “s[A]=n[A]/N.” In addition, the “support” or probability of occurrence of the consequent in the dataset may be computed as “s[C]=n[C]/N.” And the “support” or probability of occurrence of the association rule in the dataset may be computed as (s[R] (support [Rule]))=s[A→C]=n[R]/N=n[A&C]/N.

In addition, the “confidence” metric and the “lift” metric (also known as interest factor) are defined to assess the strength or predictive power of the association analysis rule and the significance of the association relative to random chance, respectively. In particular, the “confidence” metric may be computed as:

$$Confidence = s [ R ] / s [ A ] = n [ R ] / n [ A ] = n [ A \& C ] / n [ A ] .$$

In addition the “lift” metric may be computed as

$$Lift = Confidence / s [ C ] = s [ R ] / ( s [ A ] \times s [ C ] ) = ( n [ R ] \times N ) / ( n [ A ] \times n [ C ] ) = ( n [ A \& C ] \times N ) / ( n [ A ] \times n [ C ] ) .$$

A lift value at or close to 1 suggests that the association may be due to random chance (a value of 1 indicates pure random chance). Lift values>1 suggest a statistically significant positive correlation (higher values are more significant). Lift values<1 suggest a statistically significant negative correlation or anti-correlation (lower values are more significant).

For an improved understanding of selected embodiments of the present disclosure, reference is now made to FIG. 2, which illustrates a table comparison 2 of association-rule terminology usage in a retail application and in a semiconductor-testing application. As shown, the association-analysis terms in the first column are described in the second/middle column with reference to the retail-sector application and are described in the third/right column with reference to the semiconductor-test application.

In particular, the retail sector “purpose” may be to make product placement, inventory, or marketing decisions. In addition, the retail sector “transactions ID” may be “purchase receipts,” and the retail sector “items” may be “purchased items.” In terms of the key metrics, the retail sector is interested in “acceptable support levels” that are relatively “higher”, “acceptable confidence levels” that are relatively “moderate,” and “acceptable lift levels” that are “low” or “high,” depending on the specific retail application and association. For the retail sector, the “association direction” of interest is the “sufficiency” relationship that the “Antecedent (Condition)→Consequent,” and the association logic uses the “AND” logical operation. In addition, the condition (or antecedent) count is “1,” “few,” or “many” (one or more) and the consequent count is “1,” few” or “many,” (one or more) depending on the specific retail application. In the retail sector, there is no special handling of fully correlated (necessary and sufficient) items, there is not significant rule-interaction impact, and conventional metrics are used.

In contrast, the semiconductor-test sector “purpose” is to eliminate semiconductor-device tests that are applied. In addition, the semiconductor-test sector “transactions ID” may be “parts tested,” and “items” may be “failing tests.” In terms of the key metrics, the product test sector is interested in “acceptable support levels” that are relatively “lower”, “acceptable confidence levels” that are relatively “very high,” and “acceptable lift levels” that are “high.” For semiconductor testing, the “association direction” of interest is the “necessity” relationship that the “Antecedent (Condition)←Consequent,” and the association logic uses the “OR” logical operation. In addition, the condition (or antecedent) count is “1,” and the consequent count is “1,” few,” or “many,” depending on the specific application. In semiconductor testing, special handling is needed for fully correlated (necessary and sufficient) items, there is a significant multi-step approach needed for rule-interaction impact, and modified metrics are used. As explained more fully hereinbelow, conflict resolution is needed as part of the rule-interaction impact.

As disclosed more fully hereinbelow, the present disclosure seeks to apply association-analysis rules as part of a semiconductor test-reduction strategy that is needed with advanced semiconductor chips, which increasingly require device tests with greater test content, functionality, and complexity, with new failure mechanisms and fault modes, and with longer test-time requirements and costs. These testing requirements are exacerbated with stringent quality requirements from customers, especially for automotive devices. With test costs rising as a percentage (e.g., ~5-10%) of the total chip-manufacturing cost, the goal of the present disclosure is to reduce the number of tests to meet business goals with statistical rigor and without compromising field quality.

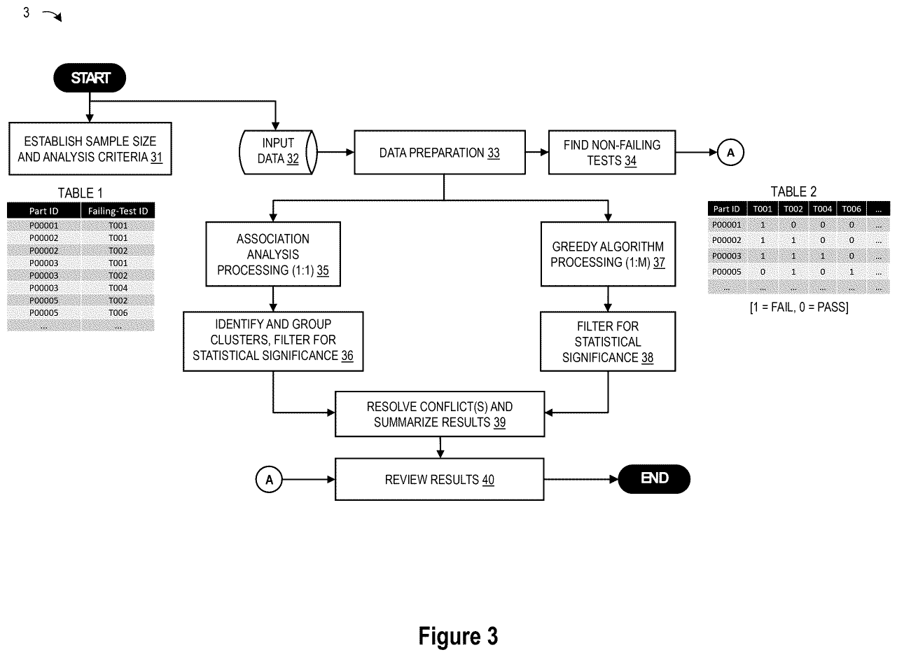

For an improved understanding of selected embodiments of the present disclosure, reference is now made to FIG. 3, which illustrates a simplified flow chart for a Fast Association Analysis for Statistical Test-Time Reduction (FAASTTR) methodology 3 for reducing the number of product tests performed. As disclosed, the FAASTTR methodology 3 uses a multi-step process which performs an association analysis (continue-on-fail/pass-through testing) in combination with a greedy algorithm to identify and remove redundant tests. The disclosed FAASTTR methodology 3 can be used at both unit probe and final test and requires continue-on-fail (CoF) testing (also known as pass-through or deferred-binning testing). The input data consists of failing tests on failing dice, with each unique die (identified by a unique die ID) listed once per failing test (Table 1). Tests that pass on failing dice are not included in the dataset. The dataset also does not include passing dice (dice that don't fail any test). Dice that fail only one test are included in the dataset. While associations are formed among multiple tests that fail together on the same dice, dice that fail only one test can prevent the formation of associations that are spurious or do not have 100% confidence. The total number of tested dice (including passing and failing dice) is determined separately to calculate the overall uncertainty from extrapolating the results from the sample dataset to the population.

Once the flow starts, the sample size (e.g., 1000 failing parts) and analysis criteria are established (step 31). In this initialization step 31, the default, as-implemented threshold for minimum part count of failing tests may be set to 1, but can be set higher. As will be appreciated, the tests may be further optimized based on minimum levels of occurrence in the dataset. For example, the FAASTTR methodology 3 may be iteratively repeated with the processing at step 31 optionally identifying, at each iterative cycle, additional tests for removal based on low/known failure rates if additional test-time reduction needed.

At step 32, the input test data is loaded into a memory or database. In selected embodiments, the input test data may be a stacked list of tested parts (e.g., P0001, P0002, P0003, etc.) with failing tests (e.g., T001, T002, T003) identified for each tested part that fails. In this example, each of the tested parts is tested in a continue-on-fail (CoF) mode. The input test data may also include a specified minimum desired occurrence (support) level.

At step 33, the input test dataset is extracted from the database and prepared, processed, and/or formatted into an appropriate input format. As shown in Table 1, the data-preparation step 33 formats the input test data in a “long format” table with defined or identified mandatory columns for a part ID and test number or name. This could be an electronic chip identifier (ECID) or equivalent. If desired, additional columns may optionally be designated to partition the analysis as desired (e.g., by test insert, test-program version, test category, manufacturing site, etc.), if needed and present in the dataset. As shown in Table 2, the data-preparation step 33 may format the input test data in a “wide format” table with defined columns for a part ID and different tests (e.g., T001, T002, etc.). In the depicted “wide format” of Table 2, there is one row for each failing part identified by a unique part ID, and the tests are in columns, arranged by test number or test sequence, where each cell of the test column has a “1” (fail) or a “0” (or a blank) (pass). As an alternative to generating Tables 1 and 2 with the data-preparation step 33, the transformation to the wide format is done when reading in the data for the association-analysis processing step 35 and the greedy algorithm processing step 37 (described hereinbelow). For example, the association-analysis processing step 35 requires the long-format Table 1, which is how the input data is set up, and the data is then transformed to the wide-format Table 2 for the greedy algorithm processing step 37. Alternatively, the input data may be initially set up in the wide format and subsequently transformed to the long format.

At an initial step in the FAASTTR methodology 3 (step 34), the test flow identifies the tests in the input test data that do not result in any test failures in the dataset and can therefore be identified for potential removal. In selected embodiments, this processing step does not involve any machine-learning analysis, but simply identifies tests for removal because they did not result in any test failures and can therefore be output as candidate removal tests (output A). If the dataset (including passing dice) is sufficiently large, then there is high confidence that these tests can be removed without significant escape risk. Alternatively, these tests can be retained in a separate, sampling program that is run periodically on a subset of the production volume for monitoring.

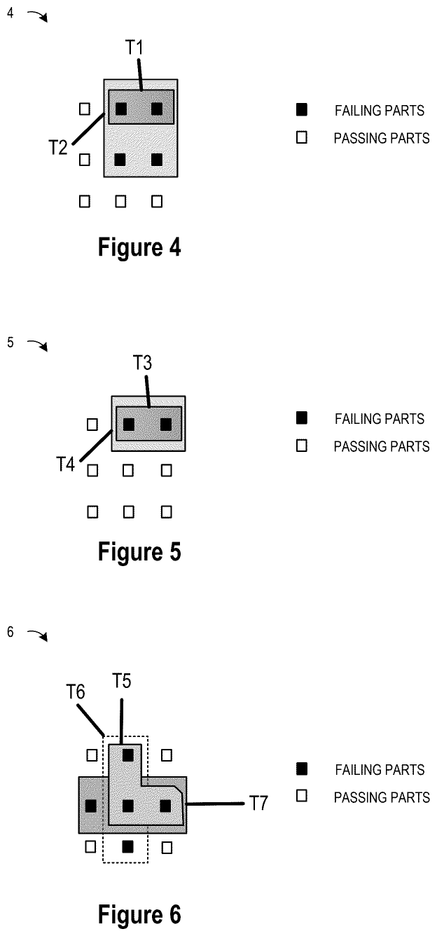

In a first association-analysis processing path, the flow applies association-analysis processing to identify 1:1 [Antecedent:Consequent (A:C)] associations at a first association-analysis processing at step 35. As disclosed, the association-analysis processing at step 35 is applied to identify, for a given part, one-to-one associations between tests where the test failure results of one test are covered by another test. To this end, the association-analysis processing at step 35 identifies directions of associations (necessary vs. sufficient) among tests that are highly positively correlated, selects the “necessary” test(s) [consequent] to keep, and selects the “sufficient” test(s) [condition/antecedent] for removal based on 100% confidence. For example, and as illustrated in FIG. 4, the association-analysis processing finds a test-failure association where every time test T1 fails, test T2 also fails. Subsequently, the first association-analysis processing path performs post-processing (step 36) to identify directly associated tests (1:1), such as by identifying and grouping clusters and filtering for statistical significance in terms of confidence, lift, and support. In selected embodiments, the post-processing step 36 may use z-score and p-value instead of lift for determining statistical significance. In this way, the post-processing step 36 may provide unique handling of fully correlated (necessary and sufficient) tests to identify at most one test to retain. In other selected embodiments, the post-processing step 36 may evaluate tests with high levels of occurrences by implementing checks to detect whether they are uniformly distributed across the dataset or correlated with specific lots, wafers, hardware, or timeframe, thereby avoiding generalizing special/unique causes). For tests with high levels of occurrences, the post-processing step 36 may optionally retain such tests in the test program, such as by pre-removing them from the analysis. The post-processing step 36 may also optionally identify tests that are determined to be retained for other reasons (e.g., customer requirements or prior history).

In the association-analysis processing step 35, the association analysis identifies associations between one consequent fail test and an antecedent fail test so that the antecedent fail test is a candidate for potential removal because it is covered by the consequent test failing on the same part(s). In particular, the association analysis has a specified condition for identifying a (antecedent or condition) test to remove because it is covered by one or more additional (consequent) tests which are kept or retained. In other words, the Consequent=>Antecedent (Condition): Necessary and the Rule=Consequent+Condition pairing. In evaluating the strength of the rule, a confidence metric is computed by dividing the probability of the rule by the probability of the antecedent (e.g., Confidence=p (Rule)/p (Antecedent)), and the lift metric is computed as Lift=Confidence/p (Consequent) [association confidence relative to random chance].

As disclosed herein, the association-analysis processing step 35 is used to identify 1:1 A:C associations. In general, the consequent test will have the same or higher number of failing parts compared to the antecedent test. The antecedent test is a candidate for potential removal because it is covered by the consequent test. The relation is shown in FIG. 4, which illustrates the results of an association analysis of an antecedent test and consequent test to identify an antecedent test that is a candidate for removal because the antecedent-test fails are covered by a consequent test. As depicted, the dice which failed a test are indicated with black squares, and the dice which passed all tests are indicated with white squares. In particular, the upper two failing dice failed test T1, and all four failing dice failed test T2. As a result, test T1 is the antecedent and can be removed because it is fully covered by test T2, the consequent.

It may be noted that an antecedent test may be separately and independently associated with multiple consequent tests, thus providing multiple association rules for the removal of the same test. Similarly, a consequent test may separately and independently cover multiple antecedent tests and can therefore be used to remove multiple tests. Furthermore, associations may also be obtained where a test that is a consequent in one rule may be an antecedent in another rule. In such cases, it follows that the consequent in the second rule is also a consequent for the antecedent in the first rule. For example, if tests T11 and T12 form an A: C association and tests T12 and T13 form another A: C association, then tests T11 and T13 will also form an A: C association. This finding can be used to consider tests T11 and T12 for removal, as they are both covered by test T13.

A special case of the 1:1 association occurs when the antecedent and consequent tests always fail in tandem. This relationship is shown in FIG. 5, which illustrates the results of an association analysis of an antecedent test and consequent test which identifies an antecedent test and a consequent test which fail in tandem. As depicted, the two failing dice failed test T3 and failed test T4. In the case where two tests fail together on the same parts, this is a case of a necessary-sufficient (N-S) cluster. N-S clusters can include two or more tests. In such cases, one of the cluster tests needs to be retained. In the standard association-analysis output, each test pair of the cluster is reported twice, with the antecedent and consequent tests interchanged. A dataset may have multiple test clusters, each of which needs to be grouped separately.

In some cases, N-S clusters may be covered by one or more additional consequent tests that are not part of the cluster. In such cases, all tests in the cluster can potentially be removed. Identification of N-S clusters requires additional post-processing of the output. In selected embodiments, N-S clusters may be identified using Pearson's correlation coefficient (φ) as a key association analysis, defined as:

$$ϕ = ( s [ R ] - ( s [ A ] \times s [ C ] ) ) / √ ( s [ A ] \times ( 1 - s [ A ] ) \times s [ C ] \times ( 1 - s [ C ] ) )$$

The value of φ ranges from −1 (perfect negative correlation) to +1 (perfect positive correlation). A value of φ=0 indicates no correlation. For N-S clusters, φ is 1 for each 1:1 association in the cluster.

In addition to the first association-analysis processing path 35, 36, the FAASTTR methodology 3 includes a second greedy algorithm processing path which applies a greedy algorithm to identify tests for removal using 1:Many (1:M) A:C associations, where M>1. An example case of the 1:M association occurs when one antecedent test is associated with two consequent tests. This relationship is shown in FIG. 6, which illustrates the results of a 1:M association analysis of an antecedent test with two consequent tests. As depicted, there are three failing dice which failed test T5, but those same failing dice also failed the “OR” combination of tests T6 and T7. In other words, test T5 is covered by the combination of tests T6 and T7 and therefore, T5 can potentially be removed.

In selected embodiments, the greedy algorithm processing path includes a greedy algorithm processing step 37 which uses a greedy algorithm to identify one-to-M associations where the fails of a first test are covered by the logical “OR” of two or more coverage tests which cover the first test fails, and therefore the first test can be removed if the coverage tests are retained. Stated another way, the greedy algorithm processing step 37 identifies a plurality of tests that together (using OR logic) are determined as necessary for a test, based on which the latter can be identified for removal. In other embodiments, the greedy algorithm processing step 37 can remove multiple tests by using OR logic to identify a plurality of tests which cover the results of the multiple tests. The greedy algorithm processing approach performed at step 37 is computationally faster than the association analysis performed at step 35, but generates results that can have lower (albeit, acceptable) statistical significance. Subsequently, the second greedy algorithm processing path performs post-processing (step 38) to filter for statistical significance in terms of confidence, lift, and support. Alternatively, the post-processing step 38 may use z-score and p-value instead of lift for determining statistical significance.

As disclosed herein, the greedy algorithm processing step 37 is used to identify 1:M (M>1) A:C associations, where a single antecedent test is covered by the combination (logical OR) of two or more consequent tests. This is a key difference from conventional association analysis used in retail, where N:M (N, M≥1) associations are formed based on a logical AND of all items within each of the antecedent and consequent sets. For example, if elements C1, C2, and C3 form a consequent set C, then the support for the consequent set s[C] for retail is computed as s[C] (retail)=n[C1&C2&C3]/N. In contrast, the support for the consequent set s[C] for semiconductor testing is computed as n[C1 OR C2 OR C3]/N.

Referring to the FAASTTR methodology 3 shown in FIG. 3, the results of the association-analysis processing path and the second greedy algorithm processing path are compared at step 39 to resolve conflicts and summarize the results to identify non-overlapping tests in the greedy algorithm processing. With the conflict-resolution processing step 39, the processing may allow tests that are identified but cannot be removed in the first association-analysis processing path (direct associations) to be checked again in the second greedy algorithm processing path (indirect associations). In particular, the conflict-resolution processing step 39 may deal with conflicts between the 1:1 association analysis recommendations (e.g., to remove an entire cluster) and the 1:M greedy algorithm recommendations. In other embodiments, the conflict-resolution processing step 39 may perform additional checks to ensure whether tests identified for removal in certain rules are also tests to keep in other rules. In other embodiments, the conflict-resolution processing step 39 may estimate the escape risk based on established quality statistics and metrics, which may include determining whether tests identified for removal are also covered by other tests in subsequent test inserts.

As disclosed herein, the conflict-resolution processing step 39 may be configured to prioritize the test-removal recommendation from the association-analysis step 35 over the test-removal recommendation from the greedy algorithm processing step 37. In such embodiments, the conflict-resolution processing step 39 prioritizes 1:1 associations over 1:k/1:M, associations (where 1<k≤M), as 1:1 associations are more intuitive and easier to understand. In other embodiments, the reverse prioritization can be done from a purely implementation perspective. For example and as illustrated with the table below, consider the conflict between a “keep” test that appears in the 1:1 recommendation from the association analysis step and a “remove” test that appears in the 1:k/1:M recommendation from the greedy algorithm processing step.

1:1 ASSOCIATION ANALYSIS STEP
TEST REMOVAL RECOMMENDATION

| 1:1 INDEX | REMOVE | KEEP |
|---|---|---|
| 1 | A | B |
| 2 | A | D |

1:M GREEDY ALGORITHM PROCESSING STEP
TEST REMOVAL RECOMMENDATION

| 1:M INDEX | REMOVE | KEEP |
|---|---|---|
| 1 | B | X1, X2 |

In this example, the conflict-resolution processing step 39 can remove test A (1:1 index 1). And if the 1:1 index 2 does not exist, then the conflict-resolution processing step 39 can remove the 1:M rule. As seen from the foregoing, if the 1:1 test to be removed (test A) by the conflicting test (B) appears in another rule (i.e., it can be removed by another test (D) that is not in conflict), the conflict-resolution processing step 39 can remove both tests A and B. However, if the 1:1 test to be removed (test A) does not appear in another rule, then the conflict-resolution processing step 39 may give up on removing B by the 1:k/1:M rule (note that X1, X2 would be more than one test in this case) in order to prioritize the 1:1 association recommendation for removing test A. It follows that, if test A is covered by test B and if test B is covered by tests X1 and X2, then test A should also be covered by tests X1 and X2. Thus, both test A and test B can potentially be removed. However, coverage of test A by a single test may be easier to interpret than coverage of test A by multiple tests, so the 1:1 association rule may be prioritized.

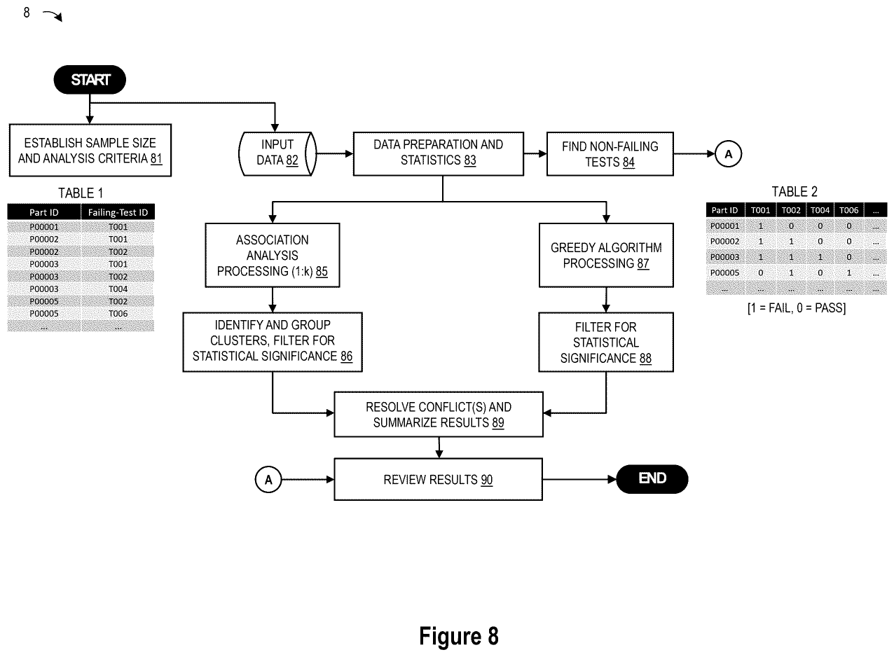

If there is a conflict between a test-removal recommendation from the 1:1 association analysis step 35 and a test-keep recommendation from the 1:M greedy-algorithm processing step 37, then the conflict-resolution processing step 39 is configured to drop the latter rule (so the test that is identified for removal by the 1:M rule will not be dropped). For the 1:M greedy algorithm processing step 37, which necessarily recommends only one rule for each test to be removed, the above case with multiple-rule associations will not come into play. However, this may happen for the 1:k association-analysis processing step 85 (described below with reference to FIG. 8), in which case a similar approach could be used to prioritize 1:1 association recommendations over 1:k/1:M association recommendations. Of course, in cases where the same test is identified for removal or for retention in both steps, this is not an issue.

In selected embodiments, the processing at step 39 may include a post-processing step to identify indirectly associated tests (1:M).

At step 40, the results are reviewed by a subject-matter expert (SME), such as the product or test engineer, for decision-making on which test(s) to remove. The SME review may include reviewing the candidate removal tests from step 34 (as indicated with the “A” input) and the results from the first association-analysis processing path and the second greedy algorithm processing path. The test times for the candidate tests to be removed are added and the total test-time reduction is calculated. If an acceptable improvement in test-time reduction is obtained, then the test flow ends. However, if there is not an acceptable improvement in test-time reduction, then the test flow assesses the escape risk for removing additional tests before re-running the test flow after changing the analysis criteria in step 31 if needed.

In the data-preparation step 33, the test flow may use ECIDs from the input data 32 to specify which parts are tested for the association analysis, and the “items” are the parts which fail tests. At the association analysis step 35, the “fail test” items are analyzed to identify and directly associate 1:1 failing tests at step 36. At step 39, the directly associated 1:1 failing tests (from step 36) are compared with the greedy algorithm processing list (from step 38) to identify non-overlapping tests in the greedy algorithm processing list which are then processed to identify indirectly associated tests (1:M). In the semiconductor-testing association analysis, the support level can be relatively low, but the confidence level should be very high.

In an alternative embodiment, the comparison processing at step 39 can be modified by comparing the results of the association-analysis processing (from step 35) with the results of the greedy algorithm processing step 37 before performing the post-processing (step 36). However, one drawback from this alternative approach is that any tests subsequently eliminated from the “remove list” during post-processing cannot be re-analyzed at a later post-processing step.

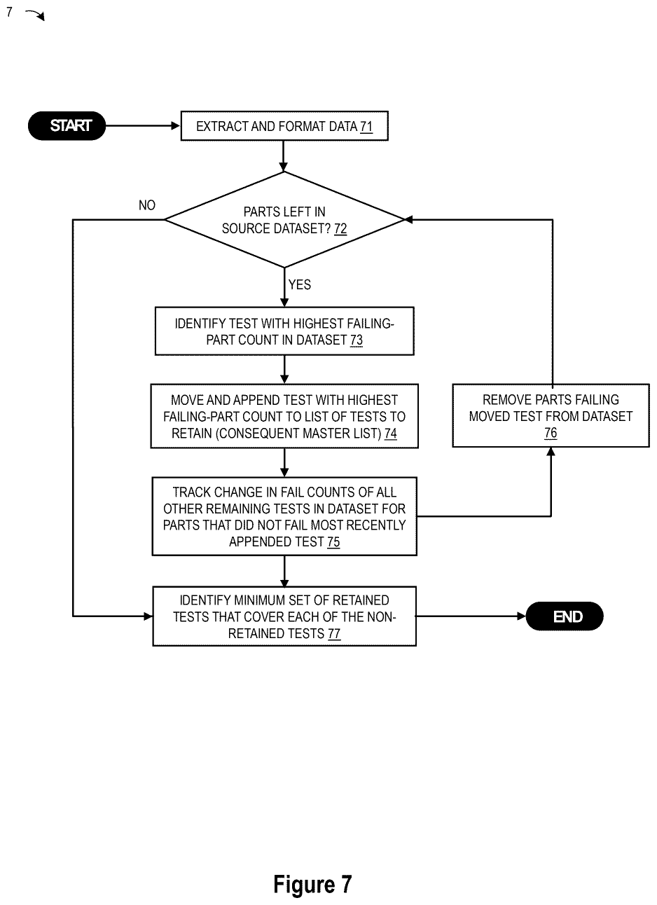

For an improved understanding of the greedy algorithm processing step 37, reference is now made to FIG. 7, which illustrates a simplified process flow chart for a greedy algorithm 7 to identify tests for removal using 1:Many (1:M) A:C associations in accordance with selected embodiments of the present disclosure. The greedy algorithm 7 sequentially identifies tests with highest fail counts in the dataset to keep and identifies the remaining tests for potential removal from the test program.

At step 71, the data is extracted from a database and suitably formatted to generate a dataset in a “wide format” table which only includes failing parts, with a unique part ID per row. As shown in FIG. 3, the greedy algorithm processing data in Table 2 has only one row for each unique failing part. The tests are in columns, arranged by test number or test sequence. Each cell of the test column has a 1 (fail) or 0/blank (pass). Thus, the same data extraction is used for the association analysis step 35 and the greedy algorithm processing step 37, but with different formatting.

At step 72, the greedy algorithm determines if there are any parts remaining in the source dataset. If there are remaining parts (affirmative outcome to detection step 72), the test with the highest failing part count in the dataset is identified at step 73, such as by generating a pareto of counts of failing tests.

At step 74, the greedy algorithm moves and appends the test with the highest fail count to a separate list which forms the set of tests to be retained. As such, this is the consequent master list of all consequent tests for the 1:M associations.

At step 75, the greedy algorithm tracks the change in fail counts of all other remaining tests in the dataset for parts that did not fail the most recently appended test in step 74.

At step 76, the greedy algorithm removes from the dataset the parts that fail the test with the highest fail count, and then returns to step 72 to determine if there are any parts remaining in the source dataset. If there are parts left in the initial dataset (affirmative outcome to detection step 72), the steps 73-76 are repeated to iteratively move the highest failing test in the remaining dataset into the retention list, and to remove parts failing that test from the dataset. These parts may also fail one or more additional tests. If two or more tests have the same failing part count at a given step, then the first test in the sequence is chosen to be moved to the consequent master list. In some embodiments, this is determined by test number or ID. At each step, as a test is identified and moved to the consequent master list, the change in fail counts of the other remaining tests is tracked and stored at step 75. Each of the remaining tests will eventually end with zero fail counts as they are either moved into the retention dataset or covered by multiple tests from the consequent master list. The foregoing process is repeated on the remaining dataset until all parts are removed. Once there are no parts left in the initial dataset (negative outcome to detection step 72), the iterative process is complete, and the minimum set of consequent tests that fully cover each of the other tests (potential candidates for removal) is identified at step 77. This forms the basis of the 1:M associations, where each part failing the antecedent test also fails one or more tests in the consequent set. As tests and parts are moved from the initial dataset to the retention tests, they may lead to removal of other tests on the same parts. Thus, tests for removal are identified based on their coverage by tests in the retention dataset.

Unlike association-analysis processing, the greedy algorithm processing will only provide one association for each antecedent test, although a consequent test may cover multiple antecedent tests. Due to the logical-OR combination of the consequents and building the associations in descending order of the counts of the highest failing tests, the support for the consequent set s[C] tends to be higher, which can reduce the statistical significance of the association. In theory, there is no limit (up to the test count in the consequent master list) to the number of consequent tests that may be used to form an association. However, in practice, this is self-limiting as larger associations will likely have weaker statistical significance. Furthermore, obtaining an engineering understanding of larger associations may not be straightforward, even if they are statistically significant. Therefore, 1:1 associations may provide an easier and more intuitive understanding of test redundancies. As a result, 1:1 associations are prioritized in the FAASTTR methodology 3, and tests that are identified for removal in the 1:1 association-analysis processing step 35 need not be re-assessed in the 1:M greedy algorithm processing step 37, thereby reducing computing overhead.

In alternative embodiments of the present disclosure, the association-analysis processing step can be used to generate 1:k associations, where 1<k≤M. However, conventional association-analysis algorithms in analysis tools or programming libraries are based on the implementation used in the retail industry and use the logical-AND combinations for multi-element antecedents and consequents. While the output of such conventional association-analysis algorithms can be post-processed to only use one element in the antecedent, associations with multi-element consequents need to be reworked to define coverage with logical OR-based combinations. To enable this, the initial output must be generated with very low confidence (based on conventional association-analysis algorithms and logical AND combinations) and then post-processed to provide OR-based rules. This can significantly increase the computing resources needed. Furthermore, some constraints (e.g., maximum number of consequent elements, minimum confidence) must be set for the initial association-analysis run. This can result in relevant rules not being generated (e.g., where confidence based on logical AND is zero because no part has all tests in the rule failing but may still be a valid rule based on logical OR of the consequent set). Another issue is that computation limitations may make it difficult to generate rules with very large consequent sets. Greedy algorithm processing is more computationally efficient though results may be statistically weaker (but still acceptable) in some cases.

For an improved understanding of selected embodiments of the present disclosure, reference is now made to FIG. 8, which illustrates a simplified flow chart for a FAASTTR methodology 8 which uses a multi-step process that performs a 1:k association analysis (continue-on-fail/pass-through testing) in combination with a greedy algorithm to identify and remove redundant tests. Similar to the approach depicted in FIG. 3, the input data consists of failing tests on failing dice, with each unique die (identified by a unique die ID) listed once per failing test (Table 1). Tests that pass on failing dice are not included in the dataset. The dataset also does not include passing dice. Dice that fail only one test are included in the dataset. While associations are formed among multiple tests that fail together on the same dice, dice that fail only one test can prevent the formation of associations that are spurious or do not have 100% confidence. The total number of tested dice (including passing and failing dice) is determined separately to calculate the overall uncertainty from extrapolating the results from the sample dataset to the population.

Once the test flow starts, the sample size (e.g., 1000 failing parts) and analysis criteria are established (step 81). In this initialization step 81, the default, as-implemented threshold for minimum part count of failing tests may be set to 1 but can be set higher. In addition, the tests may be further optimized based on minimum levels of occurrence in the dataset.

After loading the input test data into a memory or database (step 82), the input test data is extracted from the database and prepared, processed, and/or formatted into an appropriate input format (step 83), such as the “long format” for Table 1 (which is used by the 1:k association analysis step 85) or the “wide format” for Table 2 (which is used by the greedy algorithm processing step 87).

At an initial step in the FAASTTR methodology 8 (step 84), the test flow identifies the tests in the input test data that do not result in any test failures in the dataset and can therefore be identified for output as candidate removal tests (output A).

In a first association-analysis processing path, the flow applies association-analysis processing to identify 1:k [Antecedent:Consequent (A:C)] associations at a first association-analysis processing at step 85. As disclosed, the association-analysis processing at step 85 is applied to identify, for a given part, one-to-k associations (1<k≤M) between tests where the test failure results of one test are covered by up to k additional tests. For example, the association-analysis processing finds a test-failure association where every time test T5 fails, the logical “OR” combination of up to k additional tests (e.g., T6, T7) covers that T5 failure. Subsequently, the first association-analysis processing path performs post-processing (step 86) to identify initial tests (1:k), such as by identifying and grouping clusters for 1:1 associations and filtering for statistical significance in terms of confidence, lift, and support. In selected embodiments, the post-processing step 86 may use z-score and p-value instead of lift for determining statistical significance. The post-processing step 86 may also optionally identify tests that are determined to be retained for other reasons (e.g., customer requirements or prior history).

In a second greedy algorithm processing path, the flow applies a greedy algorithm to identify tests for removal using 1:Many (1:M) A:C associations (step 87), where M>1. In other words, the processing at step 87 is applied to identify one-to-M associations where the fails of a first test are covered by the logical “OR” of two or more coverage tests which cover the fails of the first test, and therefore the first test can be removed if the coverage tests are retained. The greedy algorithm processing approach performed at step 87 is faster than the association analysis performed at step 85, but generates results that can have lower (albeit, acceptable) statistical significance. Subsequently, the second greedy algorithm processing path performs post-processing (step 88) to filter for statistical significance in terms of confidence, lift, and support. Alternatively, the post-processing step 88 may use z-score and p-value instead of lift for determining statistical significance.

At step 89, the results of the first association-analysis processing path and the second greedy algorithm processing path are compared to resolve conflicts and summarize the results to identify non-overlapping test in the greedy algorithm processing. With the conflict-resolution processing step 89, the processing may allow tests that are identified but cannot be removed in the first association-analysis processing path (direct associations) to be checked again in the second greedy algorithm processing path (indirect associations). In particular, the conflict-resolution processing step 89 may deal with conflicts between the 1:1 association analysis recommendations (e.g., to remove an entire cluster) and the 1:M greedy algorithm recommendations. In other embodiments, the conflict-resolution processing step 89 may perform additional checks to ensure whether tests identified for removal in certain rules are also tests to keep in other rules. In other embodiments, the conflict-resolution processing step 89 may estimate the escape risk based on established quality statistics and metrics, which may include determining whether tests identified for removal are also covered by other tests in subsequent test inserts.

At step 90, the results are reviewed by a subject-matter expert (SME), such as a product or test engineer, who decides which test(s) to remove based on the result summary from step 89. The SME review may include reviewing the candidate removal tests from step 84 (as indicated with the “A” input) and the results from the first association-analysis processing path and the second greedy algorithm processing path. If an acceptable improvement in test time reduction is obtained, then the test flow ends. However, if there is not an acceptable improvement in test-time reduction, then the test flow assesses the escape risk for removing additional tests before re-running the test flow after changing the analysis criteria in step 81 if needed.

While the FAASTTR methodology 8 depicted in FIG. 8 is similar to the FAASTTR methodology 3 in FIG. 3, the key difference is that the association-analysis processing step 35 is performing a 1:1 analysis, while the association-analysis processing step 85 is performing a 1:k analysis, where k>1. In this way, the association-analysis processing step 85 performs some of the computations for identifying one failed test that can be covered by multiple logically OR'd failed tests with a more mathematically rigorous process, although the association-analysis processing step 85 is computationally more expensive.

In the FAASTTR methodology 8, the comparison processing at step 89 compares the results of the association analysis post-processing (step 86) with the greedy algorithm processing path post-processing (step 88) prior to performing a post-processing step in step 89 to identify additional tests (1:M). However, in an alternative embodiment, the comparison processing at step 89 can be modified by comparing the results of the association-analysis processing (from step 85) with the results of the greedy algorithm processing step 87 before performing the post-processing (step 86). However, one drawback from this alternative approach is that any tests subsequently eliminated from the “remove list” during post-processing cannot be re-analyzed at a later processing step.

Statistical Significance: To enhance the statistical rigor of the FAASTTR methodology processes disclosed herein, tests for statistical significance may be applied as part of the association-analysis (AA) processing path and the greedy algorithm processing path to ensure that the associations are not due to random chance. For example, if tests in the consequent set (either in association-analysis or greedy algorithm processing) have high failure rates in the dataset, then such tests can fully cover other tests with much lower fail counts. However, this may be due to random chance, and may not be statistically significant (i.e., full coverage may not be present for the same association in a different dataset). Associations that are likely to occur due to random chance should not be used to identify tests for removal.

As described hereinabove, lift provides a measure of the statistical significance of the association, with lift values at or close to 1 indicating that the association is due to random chance. As a simplified metric for statistical significance, the equation for Lift=s[R]/(s[A]×s[C]) can be redefined as Lift=\hat{p}/p₀, where \hat{p} is the actual probability of occurrence of the rule in the dataset, and where p₀ is the expected probability of occurrence of the rule based on random chance if the antecedent and consequent are uncorrelated and independent. A more formal metric, widely used in statistics, is the z-score (z-statistic) for a 1-proportion test which is expressed as:

$$z - score = \frac{β - {p}_{0}}{\sqrt{\frac{{p}_{0} \times ( 1 - {p}_{0} )}{N}}}$$

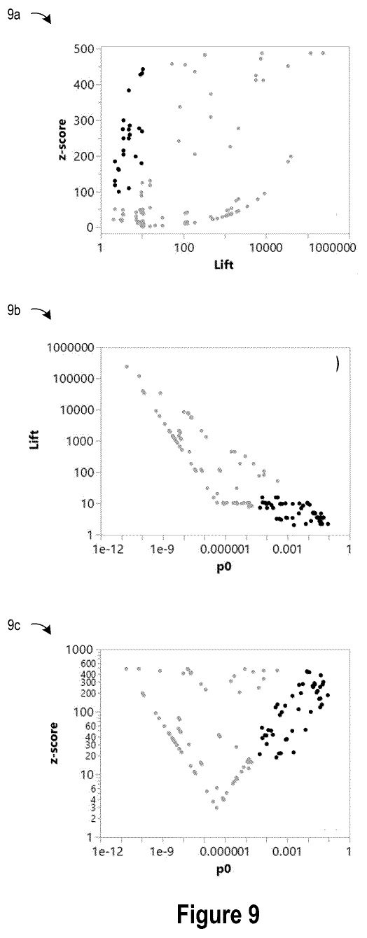

As seen from the foregoing, lift does not consider the spread of the proportion, as defined by the denominator of the equation above. A comparison of lift and z-score for a dataset is shown in FIG. 9, wherein the black markers represent data points with higher po and low lift, but high z-scores. As shown in the z-score vs. lift plot 9a, at high lift values, z-scores are also high and the two are consistent. However, at lower lift values, there can be deviation between the two metrics. As a result, using lift alone may result in statistically significant associations being missed and non-significant associations being picked up. Additionally, there is no standard threshold of statistical significance for lift. Consequently, the FAASTTR methodology may use the z-score to test the statistical significance of the association, though lift is also reported.

The z-score is the number of standard deviations, as defined by the denominator of the z-score equation (above) between \hat{p} and p₀. Treating this as a right-tailed distribution, the probability of the z-score occurring due to random chance in a rule where the antecedent and consequent are uncorrelated and independent is determined. This is the probability value (p-value) and is calculated from the cumulative distribution function (CDF), assuming a standard normal distribution, as shown in the equation:

$$p - value = α = 1 - CDF ( z - score )$$

As disclosed, the p-value is also the alpha (α), or Type I, risk, the probability of a false positive, i.e., incorrectly identifying an association that may have occurred due to random chance. For example, a z-score>2.326 results in a p-value<0.01 (i.e., less than 1% probability that the association is due to random chance). Look-up tables, online calculators, formulae in spreadsheet software, and built-in functions in programming libraries are readily available to convert z-score to p-value. The p-value threshold to determine statistically significant associations can be fixed in the flow at a pre-determined value or can be set by the user based on an acceptable risk level. Rules with p-values higher than the threshold (or z-scores lower than the corresponding threshold) are filtered out in the output report. A key advantage of this approach is that tests with relatively high failure counts in the dataset can be potentially removed if they are shown to be covered by other tests with similar or higher failure counts, as long as the associations are determined to be statistically significant.

Uncertainty: From the confidence and p-value tests used to determine the significance of the associations described above, a level of confidence and statistical rigor are obtained that the associations are significant and not due to random chance. Thus, the tests identified for removal have statistically significant coverage by other tests, regardless of their actual failure counts, and therefore have zero escape risk based on the dataset being used for the analysis. However, there is always statistical uncertainty when projecting results from a sample to a population for any data-analysis exercise. To further enhance the statistical rigor of the FAASTTR methodologies disclosed herein, tests for uncertainty may also be applied as part of the association-analysis (AA) processing path and the association-analysis path.

Assuming that the sample represents the population reasonably well, the uncertainty (U) measure is computed as U_{c,d} which quantifies the statistical uncertainty at upper c % confidence bound and for d degrees of freedom, where c is the desired confidence level (e.g., 90%) and where d is computed as d=2×(f+1), with f being the number of fails (assumed 0 for statistically significant associations with 100% confidence). In particular, the uncertainty statistic U_{c,d} may be computed as U_{c,d}=λ/SS. In this equation, λ is the upper c % confidence bound of the failure count f, and is computed as λ=χ²_{c,d}, where χ2 is the chi-squared statistic. In addition, SS is the sample size (including failing and passing units).

For example, if f=0 and c=90%, then λ=2.303. Thus, with a total of 1 million parts tested, U_{c,d} is ~2.3E-06 (~2.3 ppm) at 90% upper confidence bound for tests with zero escapes (based on statistically significant associations) in the analysis dataset. It is therefore advantageous to use large datasets to obtain strong statistically significant associations and low uncertainty.

If a confidence<100% is used (i.e., allowing some escapes (f>0)), then the following metrics for computing an escape ratio (Eᵣ) and escape fraction (E_{f}) can be assessed against pre-determined thresholds.

$${E}_{r} = 1 - Confidence = \frac{z [ A ] - s [ R ]}{s [ A ]} = \frac{n [ A ] - n [ R ]}{n [ A ]}$$

$${E}_{f , N} = \frac{n [ A ] - n [ R ]}{N}$$

$${E}_{f , SS} = \frac{n [ A ] - n [ R ]}{SS}$$

As disclosed, the escape fraction (E_{f}) can be based on either the sample size of the failing dataset (E_{f,N}) or that of the total number of units tested (passing and failing) (E_{f,SS}). Based on the actual number of fails (non-zero) being accepted, the upper c % confidence bound λ and uncertainty statistic U_{c,d} may be similarly re-calculated.

In selected embodiments, the FAASTTR methodology may be implemented in Python®. In particular, the data-preparation step 33 may extract input data from commercial database tools. In addition, the 1:1 association-analysis processing step 35 may use the fpgrowth algorithm in the mlxtend package and the flow runs on a Red Hat® Linux® virtual machine using four Intel® Xeon® E5-2690 v4 CPUs @ 2.60 GHz and 8 GB DRAM. In selected embodiments, the association analysis may be separated for different test categories (e.g., memory vs. logic) to provide ease of interpretation of results, but this is not required. In selected embodiments, upload and column definitions may be done through a web form built using the Plotly Dash® framework for Python®. In an alternative embodiment, the implementation may be done within a database tool, which has the advantage of combining the data-extraction, formatting, analysis, and post-processing steps into an integrated flow.

In the event that the fpgrowth algorithm does not have separate input arguments to set maximum antecedent and consequent element counts, there may be only a single argument for maximum rule length, which is the sum of antecedent and consequent element sizes. In this case, antecedents and consequents must contain at least 1 element for association analysis to work. For 1:1 association analysis, setting the maximum rule length to 2 suffices.

In some embodiments, issues with representing or rounding floating-point numbers may require the confidence to be set to a value>0.999999999. In large datasets, confidence<1 may lead to rules with escapes (where parts failing an antecedent test do not fail the corresponding consequent test). This may be addressed by additionally identifying and filtering out such rules by explicitly counting escapes (parts that fail the antecedent test but not the consequent test) for each association and filtering out associations with non-zero escape counts. Similarly, the correlation coefficient (φ) metric may be set to be >0.9999999999. The p-value threshold for statistical significance may be set to 0.01. Cross-checks are done to detect and resolve conflicts within each step and between the two steps.

The initial output from the 1:1 association-analysis processing step 35 may additionally be filtered in the post-processing step 36 to filter out association rules with z-scores below the threshold (p-values above the threshold), to identify N-S clusters, and to format for ease of review and interpretation. For clusters, the first test may arbitrarily be identified for retention. Final output results may be provided in spreadsheet files and stored in a shared repository. The results may include association results, z-scores, and p-values for both steps and consolidated lists of tests to keep and remove.

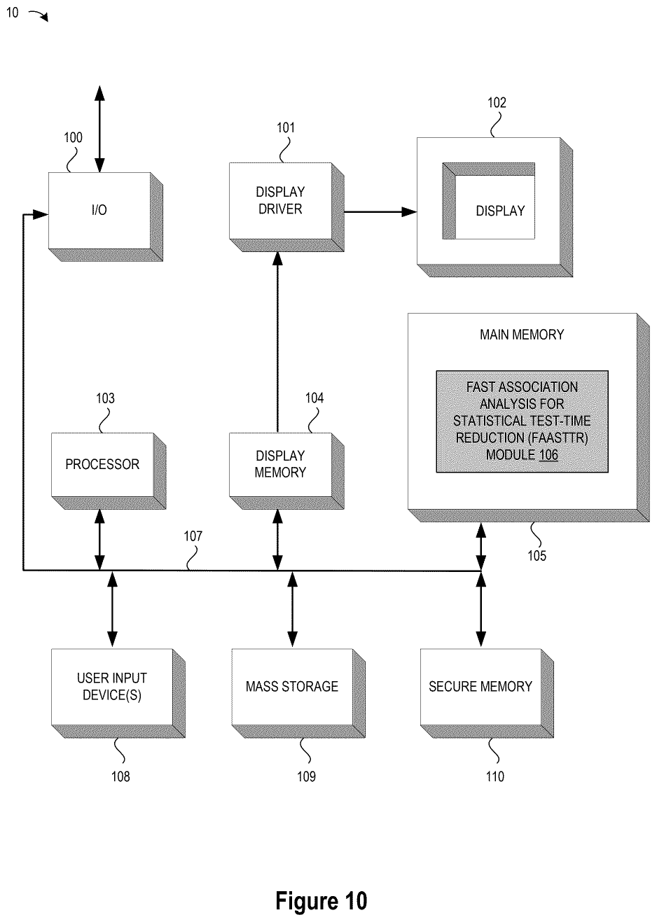

To provide additional details for an improved understanding of selected embodiments of the present disclosure, reference is now made to FIG. 10, which depicts a simplified block diagram of a computer data processing system 10 which uses a fast association analysis for statistical test-time reduction methodology to identify and eliminate redundant or unnecessary tests from an input test dataset. As disclosed, the computer data processing system 10 includes input user device(s) 108, such as a keyboard, a mouse, a scanner, a camera, a microphone, another input device, or any combination thereof, which are coupled to a bi-directional system bus 107. The input user device(s) 108 are used for introducing user input to the computer system 10 and communicating that user input to processor 103. The computer system 10 may also include a display memory 104, main memory 105, mass storage 109, and secure memory 110, all coupled to bi-directional system bus 107 along with input user device(s) 108 and processor 103. The mass storage 109 may include both fixed and removable media, such as other available mass-storage technology. The bi-directional system bus 107 may include, for example, 32 address lines for addressing display memory 104 or main memory 105. The bi-directional system bus 107 may also include, for example, an n-bit data bus for transferring data between and among the components, such as CPU or processor 103, main memory 105, display memory 104, mass storage 109, and secure memory 110, where “n” is, for example, 32 or 64. Alternatively, multiplex data/address lines may be used instead of separate data and address lines.

The computer system 10 may also include I/O device(s) 100, which provide connections to peripheral devices, such as a printer, and may also provide a direct connection to remote server-computer systems via a telephone link or to the Internet via an Internet Service Provider (ISP). I/O device(s) 100 may also include a network-interface device to provide a direct connection to remote server computer systems via a direct network link to the Internet via a POP (point of presence). Such connection may be made using, for example, wireless techniques, including digital cellular telephone connection, Cellular Digital Packet Data (CDPD) connection, digital satellite data connection, or the like. Examples of I/O devices 100 include modems, sound and video devices, and specialized communication devices such as the aforementioned network interface.

Computer programs and data are generally stored as instructions and data in mass storage 109 until loaded into main memory 105 for execution. Computer programs may also be in the form of electronic signals modulated in accordance with the computer program and data-communication technology when transferred via a network. The method and functions relating to the fast association analysis for statistical test-time reduction (FAASTTR) system and method may use software and/or programming code or instructions in the FAASTTR module 106 to process an input test dataset that is input through one or more I/O devices 108 or otherwise stored in memory (e.g., 109, 110), to identify and eliminate redundant or unnecessary tests from the input test dataset by using association-analysis processing to generate an reduced set of tests, and then to store a reduced set of tests in memory.

The processor 103, in one embodiment, is a microprocessor. Main memory 105 may be comprised of dynamic random-access memory (DRAM). Display memory 104 is a dual-ported random-access memory. One port of the display memory 104 is coupled to display amplifier or driver 101. The display amplifier or driver 101 is used to drive the display 102. Display amplifier or driver 101 is well known in the art and may be implemented by any suitable means. This circuitry converts pixel data stored in display memory 104 to a raster signal suitable for use by display 102. Display 102 is a type of monitor suitable for displaying graphic images.

The data-processing system components, programs, module, and data structures 100-110 depicted in the computer data processing system 10 are not intended to be exhaustive, but rather are representative to highlight components that can be implemented by the present disclosure. For instance, the data-processing system components may include alternate memory storage devices. In addition, multiple processor devices may be used to run the FAASTTR module 106. These and other variations are intended to be within the spirit, scope and intent of the present disclosure.

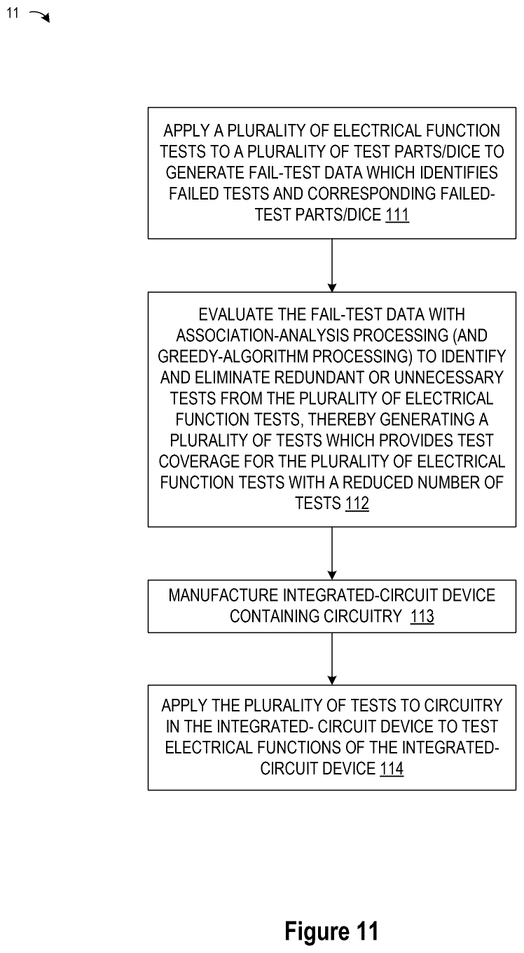

To provide additional details for an improved understanding of selected embodiments of the present disclosure, reference is now made to FIG. 11, which depicts a simplified flow diagram 11 of a method for fabricating an integrated-circuit device. As disclosed, the fabrication method 11 includes a first step 111 wherein a plurality of electrical function tests is applied to a plurality of test parts/dice to generate fail-test data that identifies failed tests and corresponding failed-test parts/dice. In addition, the disclosed fabrication method 11 includes a second step 112 wherein the fail-test data is evaluated with association-analysis processing to identify and eliminate redundant or unnecessary tests from the plurality of electrical function tests, thereby generating a plurality of tests that provide test coverage for the plurality of electrical function tests with a reduced number of tests. In selected embodiments, the evaluation step 112 may also apply greedy-algorithm processing when evaluating the fail test data. The disclosed fabrication method 11 also includes a third step 113 wherein an integrated circuit device containing circuitry is manufactured. In addition, the disclosed fabrication method 11 includes a fourth step 114 wherein the plurality of tests is applied to the circuitry in the integrated circuit device to test electrical functions of the integrated circuit device. As will be appreciated, the disclosed fabrication method 11 illustrates one possible flow for IC device manufacturing with a high-level view of the individual steps 111, 112, 113, 114 that can be used to fabricate an integrated-circuit device. However, persons skilled in the art will recognize that each step may actually include hundreds of more detailed steps. It will also be appreciated that different entities can perform the individual steps disclosed in the fabrication method 11 for IC device manufacturing.

By now, it should be appreciated that there has been provided a method, system, and apparatus for fabricating and/or testing integrated-circuit devices. As disclosed, the method includes providing an integrated-circuit (IC) device that contains circuitry, such as functional circuitry and/or test circuitry for testing electrical functions of the IC device. In addition, the method includes applying a plurality of tests to the circuitry to test electrical functions of the IC device, where the plurality of tests is generated with a test-time reduction methodology which uses association-analysis processing to evaluate fail-test data from an input test dataset to identify and eliminate redundant or unnecessary tests from the input test dataset when generating the plurality of tests. In selected embodiments, the disclosed method may also identify tests for removal that have not failed in the input test dataset prior to generating the plurality of tests. In selected embodiments, the fail-test data includes an input dataset listing of tested IC devices with one or more fail test IDs for each test applied to each tested IC device. In other selected embodiments, the plurality of tests is generated by specifying a minimum support level and confidence level for the association-analysis processing. As disclosed, selected embodiments of the association-analysis processing may identify one-to-one associations between a consequent fail test and an antecedent fail test so that the antecedent fail test is a candidate for potential removal because it is covered by the consequent fail test. In other disclosed embodiments, the association-analysis processing may identify one-to-k associations between k consequent fail tests and an antecedent fail test so that the antecedent fail test is a candidate for potential removal because it is covered by the k consequent fail tests, where k>1. In other disclosed embodiments, the association-analysis processing may identify associations between consequent fail tests and antecedent fail tests, selects one or more necessary consequent fail tests to keep, and identifies one or more sufficient antecedent tests for removal based on 100% confidence. In such embodiments, a z-score metric and p-value metric may be used to evaluate associations between consequent fail tests and antecedent fail tests for statistical significance. As further disclosed, the test-time reduction methodology may also use greedy algorithm processing to evaluate fail-test data from the input test dataset. In selected embodiments, the greedy algorithm processing may identify one-to-M associations between M logically OR'd consequent fail tests and an antecedent fail test so that the antecedent fail test is a candidate for potential removal because it is covered by the M logically OR'd consequent fail tests, where M>1. In other selected embodiments, the plurality of tests is generated by resolving conflicts between a first set of redundant or unnecessary tests identified by the association-analysis processing and a second set of redundant or unnecessary tests identified by the greedy algorithm processing. In such embodiments, conflicts between the first set of redundant or unnecessary tests and the second set of redundant or unnecessary tests may be resolved by prioritizing the first set of redundant or unnecessary tests over the second set of redundant or unnecessary tests. In selected embodiments, conflicts between the first set of redundant or unnecessary tests and the second set of redundant or unnecessary tests are resolved by removing an entire cluster of fully correlated tests if the cluster is covered by at least one other test that is necessary for the cluster but not sufficient.

In another form, there is provided a method, system, and apparatus for identifying a plurality of tests to test one or more electrical functions of an integrated-circuit (IC) device. As disclosed, the system includes an electronic processing system that is configured to perform a sequence of steps, including receiving an input test dataset listing of a plurality of tested IC devices with one or more fail-test IDs for each fail test applied to each tested IC device. In selected embodiments, the electronic processing system may also be configured to convert one or more parametric test results from the input test dataset to one or more corresponding fail tests by comparing each parametric test results to a specified test limit. The electronic processing system is also configured to apply association-analysis processing to evaluate fail tests in the input test dataset to identify a one or more first fail test removal recommendations and fail test keep recommendations. In selected embodiments, association-analysis processing is applied to identify one or more first fail-test removal recommendations and fail-test keep recommendations which meet a specified minimum support level and confidence level for the association-analysis processing. In other selected embodiments, association-analysis processing is applied to identify one-to-one associations between a consequent fail test and an antecedent fail test so that the antecedent fail test is a candidate for potential removal because it is covered by the consequent fail test. In other selected embodiments, association-analysis processing is applied to identify one-to-k associations between k consequent fail tests and an antecedent fail test so that the antecedent fail test is a candidate for potential removal because it is covered by the k consequent fail tests, where k>1. In other selected embodiments, association-analysis processing is applied to identify associations between consequent fail tests and antecedent fail tests, selects one or more necessary consequent fail tests to keep, and identifies one or more antecedent fail tests for removal based on 100% confidence. In addition, the electronic processing system is configured to apply greedy algorithm processing to evaluate fail tests in the input test dataset to identify a one or more second fail test removal recommendations and fail test keep recommendations. In selected embodiments, greedy algorithm processing is applied to identify one-to-M associations between M logically OR'd consequent fail tests and an antecedent fail test so that the antecedent fail test is a candidate for potential removal because it is covered by the M logically OR'd consequent fail tests, where M>1. In other selected embodiments, the electronic processing system may also be configured to apply greedy-algorithm processing to evaluate fail tests in the input test dataset to identify one-to-M associations between M logically OR'd consequent fail tests and an antecedent fail test so that the antecedent fail test is a candidate for potential removal that is covered by the M logically OR'd consequent fail tests, where M≥k. The electronic processing system is also configured to resolve conflicts between the one or more first fail test removal recommendations and the one or more second fail test removal recommendations to identify recommended redundant fail tests from the input test dataset. In addition, the electronic processing system is configured to remove the recommended fail tests from the input test dataset to generate the plurality of tests. In selected embodiments of the disclose system, the electronic processing system is further configured to use a z-score metric and p-value metric to evaluate associations between consequent fail tests and antecedent fail tests for statistical significance. In other selected embodiments of the disclose system, the electronic processing system is further configured to identify tests from the input test dataset for removal that have not failed in the input test dataset.

In yet another form, there is provided a method, system, and apparatus for identifying a plurality of tests to test one or more electrical functions of an integrated-circuit (IC) device. As disclosed, the method includes receiving an input test dataset listing of a plurality of tested IC devices with one or more fail-test IDs for each fail test applied to each tested IC device. The method also includes applying association-analysis processing to evaluate fail tests in the input test dataset to identify a one or more first fail test removal recommendations and fail test keep recommendations. In addition, the method also includes applying greedy algorithm processing to evaluate fail tests in the input test dataset to identify a one or more second fail test removal recommendations and fail test keep recommendations. The method also includes resolving conflicts between the one or more first fail-test removal recommendations and the one or more second fail-test removal recommendations to identify recommended redundant fail tests from the input test dataset. In addition, the method includes removing the recommended redundant fail tests from the input test dataset to generate the plurality of tests. In selected embodiments, the disclosed method may also apply the plurality of tests to a plurality of integrated-circuit (IC) devices to test electrical functions of each IC device.

Although the described exemplary embodiments disclosed herein are directed to various integrated circuit device, design, testing, and manufacture processes, the present invention is not necessarily limited to the example embodiments which illustrate inventive aspects of the present invention that are applicable to a wide variety of device design, test, and manufacture applications. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for fabricating integrated circuit devices, comprising:
providing an integrated-circuit (IC) device containing circuitry; and
applying a plurality of tests to the circuitry to test electrical functions of the IC device, where the plurality of tests is generated with a test-time reduction methodology that uses association-analysis processing to evaluate fail-test data from an input test dataset to identify and eliminate redundant or unnecessary tests from the input test dataset when generating the plurality of tests.

2. The method of claim 1, where the fail-test data comprises an input dataset listing of tested IC devices with one or more fail-test IDs for each test applied to each tested IC device.

3. The method of claim 1, where the plurality of tests is generated by specifying a minimum support level and confidence level for the association-analysis processing.

4. The method of claim 1, where the association-analysis processing identifies one-to-one associations between a consequent fail test and an antecedent fail test so that the antecedent fail test is a candidate for potential removal because it is covered by the consequent fail test.

5. The method of claim 1, where the association-analysis processing identifies one-to-k associations between k consequent fail tests and an antecedent fail test so that the antecedent fail test is a candidate for potential removal because it is covered by the k consequent fail tests, where k>1.

6. The method of claim 1, where the association-analysis processing identifies associations between consequent fail tests and antecedent fail tests, selects one or more necessary consequent fail tests to keep, and identifies one or more sufficient antecedent tests for removal based on 100% confidence.

7. The method of claim 6, further comprising using a z-score metric and p-value metric to evaluate associations between consequent fail tests and antecedent fail tests for statistical significance.

8. The method of claim 1, where the test-time reduction methodology further comprises using greedy-algorithm processing to evaluate fail-test data from the input test dataset.

9. The method of claim 8, where the greedy algorithm processing identifies one-to-M associations between M logically OR'd consequent fail tests and an antecedent fail test so that the antecedent fail test is a candidate for potential removal because it is covered by the M logically OR'd consequent fail tests, where M>1.

10. The method of claim 8, where the plurality of tests is generated by resolving conflicts between a first set of redundant or unnecessary tests identified by the association-analysis processing and a second set of redundant or unnecessary tests identified by the greedy-algorithm processing.

11. The method of claim 10, where conflicts between the first set of redundant or unnecessary tests and the second set of redundant or unnecessary tests are resolved by prioritizing the first set of redundant or unnecessary tests over the second set of redundant or unnecessary tests.

12. The method of claim 10, where conflicts between the first set of redundant or unnecessary tests and the second set of redundant or unnecessary tests are resolved by removing an entire cluster of fully correlated tests if the cluster is covered by at least one other test that is necessary for the cluster but not sufficient.

13. A system of identifying a plurality of tests to test one or more electrical functions of an integrated-circuit (IC) device, the system comprising:
an electronic processing system configured to:
receive an input test dataset listing of a plurality of tested IC devices with one or more fail test IDs for each fail test applied to each tested IC device;
apply association-analysis processing to evaluate fail tests in the input test dataset to identify a one or more first fail test removal recommendations and fail test keep recommendations; and
remove the recommended redundant fail tests from the input test dataset to generate the plurality of tests.

14. The system of claim 13, where the association-analysis processing identifies one-to-one associations between a consequent fail test and an antecedent fail test so that the antecedent fail test is a candidate for potential removal because it is covered by the consequent fail test.

15. The system of claim 13, where the association-analysis processing identifies one-to-k associations between k consequent fail tests and an antecedent fail test so that the antecedent fail test is a candidate for potential removal because it is covered by the k consequent fail tests, where k>1.

16. The system of claim 13, where the association-analysis processing identifies associations between consequent fail tests and antecedent fail tests, selects one or more necessary consequent fail tests to keep, and identifies one or more antecedent fail tests for removal based on 100% confidence.

17. The system of claim 15, where the electronic processing system is further configured to:
apply greedy-algorithm processing to evaluate fail tests in the input test dataset to identify one-to-M associations between M logically OR'd consequent fail tests and an antecedent fail test so that the antecedent fail test is a candidate for potential removal that is covered by the M logically OR'd consequent fail tests, where M≥k; and
resolve conflicts between the one or more first fail test removal recommendations and the antecedent fail test to identify recommended redundant fail tests from the input test dataset.

18. The system of claim 13, where the electronic processing system is further configured to convert one or more parametric test results from the input test dataset to one or more corresponding fail tests by comparing each parametric test results to a specified test limit.

19. A method for identifying a plurality of tests to test one or more electrical functions of an integrated-circuit (IC) device, comprising:
receiving an input test dataset listing of a plurality of tested IC devices with one or more fail-test IDs for each fail test applied to each tested IC device;
applying association-analysis processing to evaluate fail tests in the input test dataset to identify a one or more first fail-test removal recommendations and fail test keep recommendations;
applying greedy-algorithm processing to evaluate fail tests in the input test dataset to identify a one or more second fail-test removal recommendations and fail test keep recommendations;
resolving conflicts between the one or more first fail-test removal recommendations and the one or more second fail-test removal recommendations to identify recommended redundant fail tests from the input test dataset; and
removing the recommended redundant fail tests from the input test dataset to generate the plurality of tests.

20. The method of claim 19, further comprising applying the plurality of tests to a plurality of integrated-circuit (IC) devices to test electrical functions of each IC device.
